(19) United States
(12) Patent Application Publication
(10) Pub. No.: US 2016/0372620 A1
(43) Pub. Date: Dec. 22, 2016

(54) SILICON HETEROJUNCTION SOLAR CELL

(71) Applicant: COMMISSARIAT A L'ENERGIE ATOMIQUE ET AUX ENERGIES ALTERNATIVES, Paris (FR)

(72) Inventor: Jean COIGNUS, Grenoble (FR)

(73) Assignee: COMMISSARIAT A L'ENERGIE ATOMIQUE ET AUX ENERGIES ALTERNATIVES, Paris (FR)

(21) Appl. No.: 14/898,959

(22) PCT Filed: Jun. 16, 2014
(86) PCT No.: PCT/EP2014/062553

§ 371 Date: Dec. 16, 2015

(30) Foreign Application Priority Data
Jun. 17, 2013 (FR) 1355649

(51) Int. Cl. H01L 31/0747; H01L 31/028; H01L 31/18

(52) U.S. Cl. CPC H01L 31/0747; H01L 31/1868; H01L 31/1884; H01L 31/1804; H01L 31/028

(57) ABSTRACT

The invention concerns a silicon heterojunction solar cell successively comprising:
a substrate of doped crystalline silicon,
a passivation layer,
a layer of doped amorphous silicon of opposite type to the substrate,
a layer of transparent conducting material,
   said cell being characterized in that, between the substrate and the passivation layer, it comprises a layer of crystalline material having so-called “high minority carrier mobility” in which the mobility of the substrate minority carriers is greater than the mobility of said minority carriers in the substrate.

The invention also concerns a process for fabricating said solar cell.

### FIELD OF THE INVENTION

The present invention concerns a solar cell with silicon heterojunction and a process for fabricating said cell.

### BACKGROUND OF THE INVENTION

In a Silicon HeteroJunction (SHJ) solar cell the internal electrical field essential for photovoltaic effect is created by a layer of p-doped hydrogenated amorphous silicon [conventionally denoted a-Si:H(p)] deposited on an n-doped crystalline silicon substrate [conventionally denoted c-Si(n)], contrary to a conventional homojunction structure wherein the internal electrical field is obtained with a p-doped silicon/n-doped silicon junction.

Conversely, there also exist silicon heterojunction cells wherein the crystalline silicon substrate is p-doped and the hydrogenated amorphous silicon layer is n-doped.

In general, a passivation layer e.g. in intrinsic hydrogenated amorphous silicon (conventionally denoted a-Si:H(i)) is intercalated between the substrate and the doped amorphous silicon layer so as to benefit from the excellent a-Si:H(i)/c-Si(n or p) interface properties and to increase the open-circuit voltage (Voc) of the solar cell.

The low concentration of recombinant traps at the interfaces can be explained by the absence of dopant impurities in an a-Si:H(i) layer.

To limit the parasitic absorption of photons in the amorphous layers, these layers are of very narrow thickness, and a layer of transparent conducting material such as a transparent conducting oxide (TCO) is formed on the front face for lateral collection of the charges photogenerated towards the metal electrodes intended to collect the electric current produced.

In addition to low electrical resistivity, the layer of transparent conducting material must have optical properties compatible with the requirements of high yield, namely first an optical index n between the index of the external environment and that of the amorphous silicon (for the anti-reflection function) and secondly a low optical index k translating low photon absorption.

The heterojunction can be located on the front face of the cell (i.e. the side exposed to sun radiation) or else on the back face opposite the front face.

In general, on the face of the substrate opposite the face comprising the heterojunction the cell comprises a stack of a passivation layer and a doped amorphous silicon layer, of same-type doping as the substrate.

FIG. 1 is a schematic diagram of the front face A of a silicon heterojunction solar cell.

The crystalline silicon substrate is designated under reference 1.

In FIG. 1 it is an n-doped silicon substrate and the p-n junction is formed on the front face.

Substrate 1 is successively coated with a passivation layer e.g. in intrinsic amorphous silicon and with a p-doped amorphous silicon layer, each being a few nanometres thick. The assembly of these two amorphous layers carries reference number 2.

A layer 3 of transparent conducting material covers the p-doped amorphous silicon layer. Finally a metal electrode 4 is provided on the front face in contact with the layer of transparent conducting material.

Pairs of electrons e−/holes h+ are generated in the substrate 1 under the effect of photon absorption.

Under the effect of the electrical field due to the heterojunction, the holes h+ move towards the front face, pass through layer 2 of amorphous silicon and are collected by layer 3 of transparent conducting material (arrows f1 substantially perpendicular to the front face A). They are then conducted towards to the metal electrode 4 in layer 3 (arrows f2 substantially parallel to the front face A).

It is acknowledged in the literature that the compromise between conductivity and transparency of the layer of transparent conducting material is difficult to achieve [1].

With regard to the most widely used transparent conducting oxide, namely Indium Tin Oxide (ITO), the modulation of carrier concentration is ensured by oxygen doping of the layer.

The presence of a high amount of oxygen at the time of depositing the ITO layer reduces the number of oxygen vacancies and contributes towards decreasing carrier concentration.

A low carrier concentration induces greater electrical resistivity of the layer but better transparency.

Conversely, low oxygen doping induces excellent electrical conductivity of the layer (due to a high concentration of electrons) but high absorption in the infrared region.

Improvement in electrical/optical compromise of the ITO layer has reached its limits after years of optimizing deposition methods.

Alternative materials to ITO, in particular indium oxide (IO), tungsten-doped indium oxide (IWO) or zinc-doped indium oxide are currently being researched and appear to be promising.

However SHJ technology entails strict constraints regarding deposition conditions for the layer of transparent conducting material: this deposition must be conducted at low temperature and with low power so as not to deteriorate the underlying amorphous silicon layers.

These manufacturing constraints therefore limit the scope of investigative pathways.

It is one objective of the invention to further improve the yield of a silicon heterojunction solar cell.

### BRIEF DESCRIPTION OF THE INVENTION

According to the invention there is proposed a silicon heterojunction solar cell successively comprising:
a doped crystalline silicon substrate,
a passivation layer,
a doped amorphous silicon layer of opposite type to the substrate,
a layer of transparent conducting material,

said cell being characterized in that, between the substrate and the passivation layer, it comprises a layer of crystalline material having so-called “high minority carrier mobility” in which the mobility (μₘ) of the substrate minority carriers is greater than the mobility of said minority carriers in the substrate.

By “intrinsic silicon” is meant silicon not containing any dopant, or at least in which no dopant has been intentionally added during the formation of the material. At all events, it is considered that the silicon is intrinsic if its concentration of active dopants is lower than 1^{E}15/cm³.

For this purpose, the depositing of intrinsic silicon in amorphous or crystalline form is conducted in an enclosure not contaminated by dopant impurities.

By “micro-doped silicon” is meant silicon having a concentration of active dopants of between 1^{E}15 and 1^{E}17/cm³.

By doped silicon is meant silicon having a concentration of active dopants higher than 1^{E}17/cm³.

Said layer of material with high minority carrier mobility is in contact with the substrate.

In particularly advantageous manner, the thickness of the layer of material with high minority carrier mobility is selected so as to be thinner than the critical thickness on and after which crystalline defects occur in said layer when said material is grown by epitaxy on the crystalline silicon substrate.

Preferably the thickness of the layer of material with high minority carrier mobility is between 3 and 25 nm.

According to one embodiment of the invention, the substrate is n-doped, the minority carriers then being holes.

According to one preferred embodiment, the material with high hole mobility is an alloy of silicon and germanium of Si₁₋ₓGeₓ type with 0<x≦1.

According to another embodiment, the substrate is p-doped, the minority carriers then being electrons.

In this case, the material with high electron mobility is advantageously a GaAs or InGaAs alloy.

According to one particularly advantageous embodiment of the invention said cell, between the layer of material with high minority carrier mobility and the passivation layer, further comprises a layer of intrinsic crystalline silicon the effect of which is to improve the quality of the interface between said layer and the passivation layer.

The thickness of said layer of intrinsic crystalline silicon is advantageously between 1 and 5 nm.

A further subject concerns a process for fabricating a solar cell such as described above.

Said process comprises the forming on a doped crystalline silicon substrate of the following successive layers:
a passivation layer,
a doped amorphous silicon layer of opposite type to the substrate,
a layer of transparent conducting material,
   said process being characterized in that, before the formation of said layers, it comprises the epitaxial growth on the substrate of a layer of crystalline material having so-called “high minority carrier mobility”, in which the mobility (μₘ) of the substrate minority carriers is higher than the mobility of said minority carriers in the substrate.

In particularly advantageous manner, the thickness of the layer of material with high minority carrier mobility is selected so as to be thinner than the critical thickness on and after which crystalline defects occur in said layer.

Preferably, the thickness of the material layer with high minority carrier mobility is between 3 and 25 nm.

According to one embodiment of the invention, the substrate is n-doped, the minority carriers then being holes.

According to one preferred embodiment, the material with high hole mobility is an alloy of silicon and germanium of Si₁₋ₓGeₓ type with 0<x≦1.

According to another embodiment, the substrate is p-doped, the minority carriers then being electrons.

In this case, the material with high electron mobility is advantageously a GaAs or InGaAs alloy.

According to one particularly advantageous embodiment, the process further comprises the epitaxial growth of a layer of intrinsic crystalline silicon on said layer of material with high minority carrier mobility.

The thickness of said intrinsic crystalline silicon layer is advantageously between 1 and 5 nm.

### BRIEF DESCRIPTION OF THE DRAWINGS

Other characteristics and advantages of the invention will become apparent from the following detailed description given with reference to the appended drawings in which:

FIG. 1 is a schematic diagram of the front face of a conventional silicon heterojunction solar cell;

FIG. 2 illustrates the band diagram of the front face of a conventional silicon heterojunction solar cell;

FIG. 3 is a cross-sectional view of the front face of a silicon heterojunction solar cell conforming to the invention;

FIG. 4 shows the change in critical thickness of a layer of silicon-germanium alloy as a function of the proportion of germanium in the alloy;

FIG. 5 is a schematic diagram of the front face of a silicon heterojunction solar cell conforming to the invention.

It is specified that for reasons of clarity of illustration, the thicknesses of the different layers are not drawn to scale.

### DETAILED DESCRIPTION OF EMBODIMENTS OF THE INVENTION

It is proposed, on the side of the cell comprising the heterojunction, to intercalate an additional layer between the crystalline silicon substrate having one type of doping and the passivation layer, so as to increase conductivity in a layer called inversion layer present at the interface between the passivation layer and the crystalline silicon substrate.

The presence of the additional layer is intended to promote a conduction pathway parallel to the pathway observed in the layer of transparent conducting material, which advantageously allows use of a transparent conducting material that is less electrically conductive than those usually used and hence having better optical properties.

It is possible for example to modulate the thickness of the layer of transparent conducting material and/or the intrinsic conductivity of said material so that said material is optically improved and hence less electrically conductive.

In general, the transparent conducting material may be an indium transparent conducting oxide (such as ITO, IO, IWO, etc.) having a low thermal budget for deposition and adapted work function.

In an indium transparent conducting oxide, oxygen doping is sufficient to obtain significant modulation of the conductivity/transparency compromise.

FIG. 2 illustrates the band diagram of the front face of a conventional silicon heterojunction solar cell with an n-doped crystalline silicon substrate (c-Si(n)), a passivation layer in intrinsic amorphous silicon (a-Si:H(i)) and a p-doped amorphous silicon layer (a-Si:H(p)).

The dotted line represents the Fermi level E_{f}.

As can be seen in this diagram, there is indeed an inversion layer at the interface between the a-Si:H(i) layer and the substrate c-Si(n) [2, 3].

This inversion layer is designated by the encircled region denoted INV.

Due to the internal electrical field imposed by the a-Si:H(p) layer, the minority carrier concentration of the substrate (holes h+) is greater at the interface than the majority carrier concentration (electrons e−).

Although this inversion layer has already been evidenced in heterojunction cells, up until now it has not appeared to be a possible lever able to allow improvement in yields.

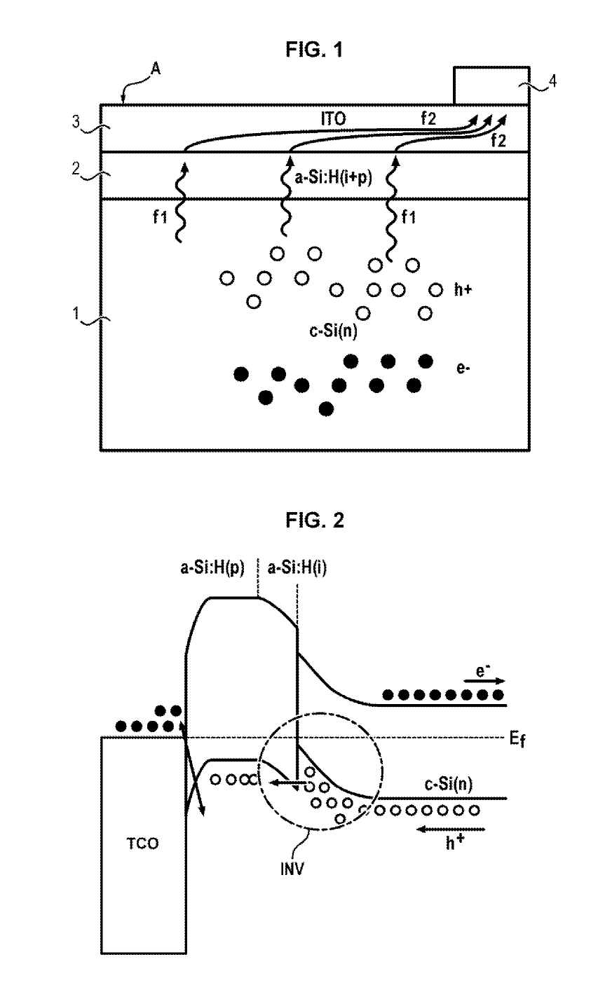

Yet the Applicant proposes improving the conductivity of the inversion layer to provide another pathway for the collection of charge carriers other than the one conventionally known via the layer in transparent conducting material (TCO) and illustrated FIG. 1.

This allows circumventing the electrical/optical compromise encountered up until now for the layer of transparent conducting material, thereby opening up prospects of improved yields for SHJ cells.

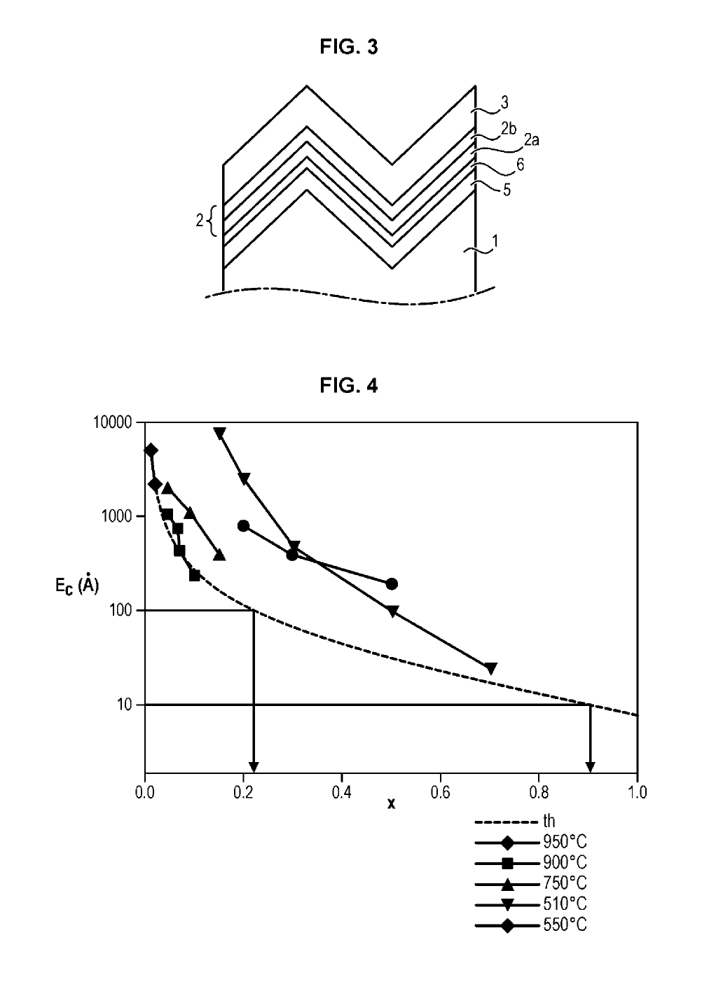

FIG. 3 is a cross-sectional view of the front face of a silicon heterojunction solar cell according to the invention.

In the example described herein the substrate is n-doped and the amorphous silicon is p-doped.

In this case the minority carriers of the substrate are holes.

However, the invention also applies to a cell in which the substrate is p-doped and the amorphous silicon is n-doped.

In this case the minority carriers of the substrate are electrons.

Also, the example described herein concerns a cell in which the junction between the silicon substrate and the amorphous silicon is formed on the front face.

However the invention also applies to a so-called “inverted emitter” cell where the junction between the silicon substrate and the amorphous silicon is formed on the back face.

As can be seen in FIG. 3 the cell, like a conventional cell, comprises on its front face:
a substrate 1 in n-doped silicon,

- a passivation layer 2a; according to one embodiment said layer is a layer of intrinsic amorphous silicon (or p- micro-doped),

- a layer 2b in p-doped amorphous silicon, the stack of layers 2a and 2b having reference number 2,

- a layer 3 in transparent conducting material.

In addition, the silicon heterojunction solar cell may also comprise other layers on the opposite side of the substrate: a passivation layer, a layer in-doped amorphous silicon of same doping as the substrate (hence n in this case) and a layer of transparent conducting material.

In this cell an additional layer is also inserted between the substrate 1 and the passivation layer 2a.

This additional layer is a layer 5 of crystalline material having so-called “high hole mobility” and is intended to improve conduction in the inversion layer.

Carrier mobility (holes or electrons) is generally denoted μₘ.

By “high hole mobility” is meant herein hole mobility that is strictly higher than the mobility of the holes (which are the minority carriers of the n-type substrate) in the silicon substrate which is in the order of 450 cm²/Vs.

Among those materials having higher hole mobility than silicon, particular mention can be made of a silicon and germanium alloy, germanium (μₘ=1900 cm²/Vs), gallium antimonide GaSb (μₘ=850 cm²/Vs) or indium antimonide (μₘ=1250 cm²/Vs).

Conversely, if the silicon substrate is p-doped, the minority carriers of said substrate are electrons.

Amongst those materials having higher electron mobility than the silicon substrate particular mention can be made of a GaAs or InGaAs alloy.

The invention therefore more generally uses a material with “high mobility of substrate minority carriers” wherein the mobility of said substrate minority carriers is strictly higher than the mobility of said carriers in the substrate.

It is to be pointed however that the mobility of holes or electrons in these materials in the form of a layer epitaxied on a crystalline silicon substrate differs from their intrinsic mobility.

The lattice mismatch with silicon leads to mechanical stress in the epitaxied layer which modifies the conduction properties of the layer.

Persons skilled in the art, for an envisaged material, are able to fabricate a layer of this material via epitaxy on a crystalline silicon substrate and to measure hole or electron mobility in said layer e.g. via Hall-effect measurement.

Also, the mechanical stress imposed by the silicon lattice parameter may be a source of defects at the interface and of dislocations.

These defects and dislocations are dependent on the thickness of the epitaxied layer.

In manner known per se, the term critical thickness is given to the maximum thickness below which the epitaxied layer is free of crystalline defects.

FIG. 4 illustrates the change in critical thickness E_{c} of a silicon-germanium alloy Si₁₋ₓGeₓ as a function of the concentration x in germanium, for different epitaxy temperatures. This data is derived from [4].

For example 10 nm of SiGe containing 20% germanium can be epitaxied without the onset of defects, the critical thickness falling to 1 nm for a germanium concentration of 90%.

Consideration must therefore be given both to the target thickness and to the germanium concentration.

If the substrate is n-doped, the SiGe alloy is the preferred material for implementing the invention since the epitaxy of this material is fully mastered (Chemical Vapour Deposition—CVD).

In addition, the thermal budget required for epitaxy of this layer has no impact on the layers of amorphous silicon since these are formed at a later stage.

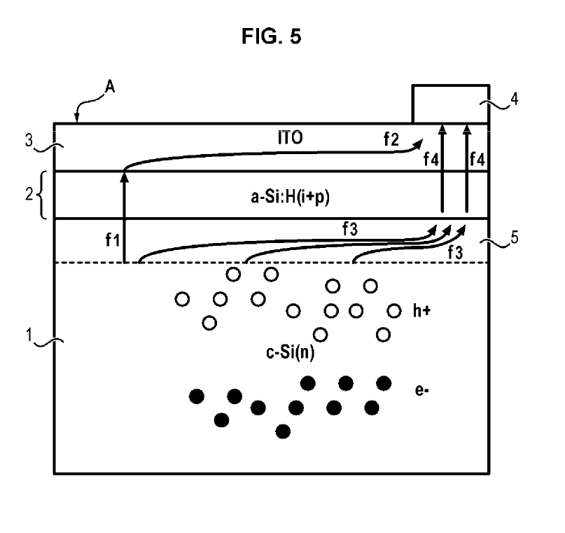

FIG. 5 is a block diagram of the front face of a silicon heterojunction solar cell conforming to the invention (the substrate here is n-doped).

On account of the insertion of the material with high hole mobility between the crystalline silicon substrate and the layer of amorphous silicon, another conduction pathway has been able to form within the cell. It is a pathway parallel to the pathway observed in the layer of transparent conducting material.

Electron e−/hole h+ pairs are generated in the substrate 1 under the effect of photon absorption.

Under the effect of the electrical field due to the heterojunction, the holes h+ move towards the front face.

In conventional manner, some of the holes h+ pass through the amorphous silicon layer 2 and are collected by the layer 3 of transparent conducting material (arrow f1 substantially perpendicular to the front face A). They are then conducted towards the metal electrode 4 in layer 3 (arrow f2 substantially parallel to the front face A).

However, due to the presence of the layer with high hole mobility at the interface between the substrate 1 and the amorphous silicon layer 2, some of the holes h+ are conducted in the layer 5 with high hole mobility, underneath the amorphous silicon layer (arrows f3), and these holes then pass through the amorphous silicon layer and the layer of transparent conducting material perpendicular to the metal electrode 4 (arrows f4).

The layer of material with high hole mobility therefore has the effect of improving the conductivity of the inversion layer in the solar cell.

For a p-doped substrate, the layer of material with high electron mobility provides the same effect.

In a cell conforming to the invention, the share of charges collected by the transparent conducting material is therefore decreased to the benefit of the share of the inversion layer.

This makes it possible to reduce the conductivity of the layer of transparent conducting material without deteriorating the form factor (FF) of the solar cell, and hence to improve the optical properties of the layer of transparent conducting material and the short-circuit current (lsc) of the cell.

Additionally, the improvement in lateral charge collection allows the space between the metal electrodes to be increased and cell shadowing to be reduced, so that a gain in short-circuit current can be expected.

Having regard to the constraints of high yield cells, which require maintaining of interface quality and quality of cell constituent materials, the layer of material with high minority carrier mobility is obtained by epitaxy on the crystalline silicon substrate after texturing and cleaning of the substrate.

In addition, as explained above, the thickness of the layer 5 of material with high minority carrier mobility is sufficiently thin to prevent the onset of dislocations.

Depending on the doping level of the substrate 1 and of the material selected for layer 5, the thickness of layer 5 is between 3 and 25 nm, preferably between 5 and 20 nm.

The stacking of the passivation layer, the doped amorphous silicon layer of opposite type to the substrate and of the layer of transparent conducting material is then carried out in conventional manner.

Advantageously, before forming said stack, it is possible to deposit a very thin layer 6 of intrinsic crystalline silicon on the layer of material with high minority carrier mobility.

The thickness of said intrinsic crystalline silicon layer is typically between 1 and 5 nm.

The function of this layer 6 is to preserve the quality of the a-Si:H(i)-c-Si interface.

In manner known per se, the forming of the stack of amorphous layers and transparent conducting material typically comprises the following steps:
on the side comprising the heterojunction, deposition of the passivation layer 2a e.g. in intrinsic or micro-doped a-Si:H of opposite type to the substrate, this layer being deposited on layer 5 of material with high minority carrier mobility, or optionally on the layer 6 in intrinsic crystalline silicon. This deposition can be performed by Plasma—Enhanced Chemical Vapour Deposition—PECVD). The thickness of the layer 2a is typically between 5 and 15 nm;
on the passivation layer 2a, deposition of the layer 2b of a-Si:H having opposite type to the substrate. This deposition can also be performed by PECVD. The thickness of layer 2b is typically between 2 and 10 nm;
on the side opposite the heterojunction, deposition of a passivation layer e.g. in intrinsic or micro-doped a-Si:H of same typing doping as the substrate. This deposition can be performed using PECVD. The thickness of said layer is typically between 2 and 15 nm;
on said passivation layer, deposition of an a-Si:H layer having same type doping as the substrate. This deposition can also use PECVD. The thickness of said layer is typically between 5 and 30 nm;
on the front face, deposition of layer 3 of transparent conducting material e.g. ITO. This deposition can be performed using Physical Vapour Deposition (PVD). The thickness of layer 3 is typically between 50 and 150 nm;
on the back face, deposition of a layer of transparent conducting material e.g. ITO. This deposition can be performed using PVD. The thickness of said layer is typically between 50 and 150 nm;
forming electrodes by metallizing the front face and back face, e.g. by screen printing.

As set forth above, the invention is not limited to a solar cell having an n-doped substrate and with the heterojunction formed on the front face, but also applies to SHJ solar cells having a p-doped substrate and/or having the heterojunction on the back face.

### REFERENCES

[1] Z C Holman et al., IEEE Journal of Photovoltaics 2, p. 7, 2012
[2] J P Kleider et al., Nanoscale Research Letters 6, p. 152, 2011
[3] J V. Li et al., Journal of Applied Physics 110, 114502, 2011
[4] Y. Bogumilowicz, Thèse de Doctorat 2005

1. A silicon heterojunction solar cell successively comprising:
a substrate of doped crystalline silicon,
a passivation layer,
a layer of doped amorphous silicon of opposite type to the substrate,
a layer of transparent conducting material,
said cell being the cell further comprising, between the substrate and the passivation layer, a layer of crystalline material having so-called “high minority carrier mobility” in which the mobility of the substrate minority carriers is greater than the mobility of said minority carriers in the substrate.

2. The solar cell of claim 1, wherein said layer of material having high minority carrier mobility is in contact with the substrate.

3. The solar cell of claim 1, wherein the thickness of the layer of material having high minority carrier mobility is selected so that said layer is thinner than the critical thickness on and after which crystalline defects occur in said layer when said material is grown by epitaxy on the crystalline silicon substrate.

4. The solar cell of claim 1, wherein the thickness of the layer of material having high minority carrier mobility is between 3 and 25 nm.

5. The solar cell of claim 1, wherein the substrate is n-doped, the minority carriers then being holes.

6. The solar cell of claim 5, wherein the material having high minority carrier mobility is an alloy of silicon and germanium of Si₁₋ₓGeₓ type with 0<x≦1.

7. The solar cell of claim 1, wherein the substrate is p-doped, the minority carriers then being electrons.

8. The solar cell of claim 7, wherein the material having high minority carrier mobility is a GaAs or InGaAs alloy.

9. The solar cell of claim 1, further comprising, between the layer of material having high minority carrier mobility and the passivation layer, a layer of intrinsic crystalline silicon.

10. The solar cell of claim 9, wherein the thickness of the layer of intrinsic crystalline silicon is between 1 and 5 nm.

11. The solar cell of claim 1, wherein the passivation layer is a layer of intrinsic or micro-doped amorphous silicon of opposite type to the substrate.

12. A process for fabricating a silicon heterojunction solar cell comprising forming, on a doped crystalline silicon substrate, the following successive layers:
a passivation layer,
a layer of doped amorphous silicon of opposite type to the substrate,
a layer of transparent conducting material,
said process further comprising, before the formation of said passivation, doped amorphous silicon and transparent conducting material layers, epitaxial growth on the substrate of a layer of crystalline material having so-called “high minority carrier mobility” in which the mobility of the substrate minority carriers is greater than the mobility of said minority carriers in the substrate.

13. The process of claim 12, wherein the thickness of the layer of material having high minority carrier mobility is selected so that it is thinner than the critical thickness on and after which crystalline defects occur in said layer.

14. The process of claim 12, wherein the thickness of the layer having high minority carrier mobility is between 3 and 25 nm.

15. The process according of claim 12, wherein the substrate is n-doped, the minority carriers then being holes.

16. The process of claim 15, wherein the material with high minority carrier mobility is an alloy of silicon and germanium of Si₁₋ₓGeₓ type with 0<x≦1.

17. The process of claim 12, wherein the substrate is p-doped, the minority carriers then being electrons.

18. The process of claim 17, wherein the material having high minority carrier mobility is a GaAs or InGaAs alloy.

19. The process of claim 12, further comprising the epitaxial growth of a layer of intrinsic crystalline silicon on said layer of material having high minority carrier mobility.

20. The process of claim 19, wherein the thickness of the intrinsic crystalline silicon layer is between 1 and 5 nm.
